(19) United States
(12) Patent Application Publication
(10) Pub. No.: US 2026/0278212 A1
(43) Pub. Date: Sep. 17, 2026

(54) METHOD AND ELECTRONIC DEVICE FOR PREDICTING LENS DEFECTS

(71) Applicant: LG INNOTEK CO., LTD., Seoul (KR)

(72) Inventors: Tae Woo LEE, Seoul (KR); Sang Woo KIM, Seoul (KR); Joon Hyung KIM, Seoul (KR); Dong Wook SHIN, Seoul (KR); Jae Wook JUNG, Seoul (KR)

(21) Appl. No.: 19/168,006

(22) PCT Filed: Apr. 26, 2024
(86) PCT No.: PCT/KR2024/005663

§ 371 Date: Sep. 23, 2025

(30) Foreign Application Priority Data
Apr. 28, 2023 (KR) 10-2023-0056223
Apr. 26, 2024 (KR) 10-2024-0055791

(51) Int. Cl. G06F 30/27

(52) U.S. Cl. CPC G06F 30/27

(57) ABSTRACT

An embodiment of the present invention discloses to a method for predicting lens defects, the method comprising the steps of: generating a dataset that is through-focus data by applying certain lens defects; performing machine learning on the basis of the dataset; and outputting a lens defect result when test through-focus data is input.

### TECHNICAL FIELD

Embodiments of the present invention relate to a method and electronic device for predicting lens defects.

### BACKGROUND ART

Industrial artificial intelligence (AI) is a technology focused on optimizing and automating industrial processes, such as monitoring device performance, predicting maintenance needs, and improving production efficiency.

Particularly, industrial AI is often designed to operate in complex and high-risk environments which is more specialized than general AI and in which accuracy and reliability are important. Additionally, industrial AI is often integrated with other industrial systems and technologies, such as sensors, robotics, and IoT devices, to provide complete solutions for optimizing industrial processes.

Particularly, with the introduction of industrial AI, traditional inspection of manufacturing processes based on statistical control has limitations in terms of accuracy and speed, as failures may occur even with the complexity and minute errors of data generated from complex processes and numerous pieces of equipment.

Recently, there has been a growing demand for industrial AI to apply deep learning models to the camera module manufacturing process, overcoming the shortcomings of existing methods and easily predicting or identifying the causes of failures or defects.

In response to this, it is also time to address issues such as the complexity of manufacturing processes, such as an active alignment process, in the manufacturing of camera modules.

### DISCLOSURE

### Technical Problem

The technical problem to be solved by an embodiment of the present invention is to provide a method and electronic device for predicting lens defects which accurately predict lens deformation or defect information by performing learning with through-data on lens deformation.

In addition, a method and electronic device for predicting lens defects in which directions of supervised learning and dataset generation are opposite may be provided.

The problem to be solved in the embodiment is not limited to this, and it can be said that the purpose or effect that can be understood from the solution or implementation form of the problem described below is also included.

### Technical Solution

A method for predicting lens defects according to an embodiment of the present invention includes a step of generating a dataset that is through-focus data by applying a predetermined lens defect; a step of performing machine learning based on the dataset; and a step of outputting a lens defect result when test through-focus data is input.

The predetermined lens defect may include position distortion or a surface shape error.

The step of generating the dataset may include a step of classifying the dataset by the lens defect.

The method may further include a step of further classifying the classified dataset by position.

The machine learning may be based on a fully connected neural network that follows a Gaussian distribution (N-Gaussian) for defects in a single lens.

In the machine learning, a distribution of lens defects may be set to follow a Gaussian distribution based on a threshold value that determines pass/fail.

The machine learning may predict defects in a single lens by weighting the Gaussian distribution.

The generation of the dataset and the performance of the machine learning may be performed in opposite directions.

The through-focus data may be a spatial frequency response in a tangential T or sagittal S direction.

In the outputting step, the lens defect result may be predicted based on a multi-output regression model.

An electronic device according to an embodiment includes: a memory; and a processor connected to the memory, wherein the processor generates a dataset that is through-focus data by applying a predetermined lens defect, performs machine learning based on the dataset, and outputs a lens defect result when test through-focus data is input.

The predetermined lens defect may include position distortion or a surface shape error.

The processor may classify the dataset by the lens defect when generating the dataset.

The processor may further classify the classified dataset by position.

The machine learning may be based on a fully connected neural network that follows a Gaussian distribution (N-Gaussian) for defects in a single lens.

In the machine learning, a distribution of lens defects may be set to follow a Gaussian distribution based on a threshold value that determines pass/fail.

The machine learning may predict defects in a single lens by weighting the Gaussian distribution.

The generation of the dataset and the performance of the machine learning may be performed in opposite directions.

The through-focus data may be a spatial frequency response in a tangential T or sagittal S direction.

The lens defect result may be predicted based on a multi-output regression model.

### Advantageous Effects

According to an embodiment of the present invention, it is possible to implement a method and electronic device for predicting lens defects which accurately predict lens deformation or defect information by performing learning with through-data on lens deformation.

In addition, it is possible to implement a method and electronic device for predicting lens defects in which directions of supervised learning and dataset generation are opposite.

In addition, an embodiment can implement a method and electronic device for predicting lens defects which accurately determine the tilt margin of a lens by predicting a defect of the lens, and significantly reduce the probability of failure during an active alignment (AA) process based on the determined tilt margin.

Additionally, an embodiment can implement a method and electronic device for predicting lens defects that can immediately identify the cause of an active alignment (AA) defect, thereby reducing the design of experiments (DOE) required for defect cause analysis.

Additionally, an embodiment can implement a method and electronic device for predicting lens defects which enable better yield management and provide a strong basis for critical decision-making in the lens manufacturing process.

Furthermore, an embodiment can implement a method and electronic device for predicting lens defects that can significantly improve the lens manufacturing process by accurately predicting the causes of lens defects or deformation, as well as provide valuable insights for quality control and process optimization, resulting in reduced production costs and improved overall efficiency.

The various beneficial advantages and effects of the present invention are not limited to the above-described contents, and will be more easily understood in the process of describing specific embodiments of the present invention.

### DESCRIPTION OF DRAWINGS

FIG. 1 is a block diagram showing the configuration of an electronic device according to an embodiment.

FIG. 2 is a flowchart for describing a method for predicting lens defects according to the embodiment.

FIG. 3 is a view for describing a process of generating a dataset in the method for predicting lens defects according to the embodiment.

FIGS. 4(a) and (b) are views for describing the lens defect in FIG. 3.

FIG. 5 is a view for describing a fully connected neural network in the method according to the embodiment.

FIG. 6(a) to (c) are views for describing active alignment to describe the effect of the method according to the embodiment.

FIG. 7(a) to (d) are views for describing the effect of the method according to the embodiment.

FIG. 8 is a scatter plot of predicted values and actual values by the method according to the embodiment.

FIG. 9 is an evaluation index (R-Squared) for the method according to the embodiment.

FIG. 10 is a view showing through-focus data of predicted values and actual values by the method according to the embodiment.

### MODES OF THE INVENTION

Since the present invention can be modified in various ways and have many embodiments, specific embodiments are illustrated and described in the drawings. However, this is not intended to limit the present invention to any particular embodiment, and is to be understood to include all modifications, equivalents, or substitutions that fall within the scope of the ideas and techniques of the present invention.

Although terms that include ordinal numbers, such as second, first, and the like may be used to describe various components, the components are not limited by the terms. Terms are merely used to distinguish one component from another. For example, a second component may be referred to as a first component, and similarly, the first component may also be referred to as the second component, without departing from the scope of the present invention. The term and/or includes any combination of a plurality of related described items or any one of a plurality of related described items.

When it is said that a component is “connected” or “coupled” to another component, although it should be understood that it may be directly connected or coupled to that other component, there may also be other components therebetween. On the other hand, when it is said that a component is “directly connected” or “directly coupled” to another component, it should be understood that there are no other components therebetween.

The terminology used in the present application is for the purpose of describing specific embodiments only and is not intended to limit the present invention. Singular expressions include plural expressions unless the context clearly indicates otherwise. In the present application, it should be understood that terms such as “includes” or “has” are intended to specify the presence of a feature, number, step, operation, component, part or combination thereof described in the specification, but do not exclude in advance the possibility of the presence or addition of one or more other features, numbers, steps, operations, components, parts or combinations thereof.

Unless otherwise defined, all terms used herein, including technical or scientific terms, have the same meaning as commonly understood by one of ordinary skill in the art to which the present invention belongs. Terms defined in commonly used dictionaries should be interpreted to have a meaning consistent with their meaning in the context of the related art, and will not be interpreted in an idealized or overly formal sense unless expressly defined in this application.

Hereinafter, embodiments will be described in detail with reference to the attached drawings. Regardless of the drawing numbers, identical or corresponding components are denoted by the same reference numbers, and redundant descriptions thereof will be omitted.

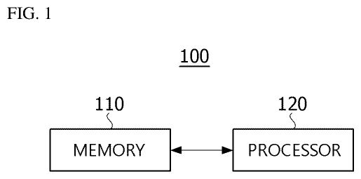

FIG. 1 is a block diagram showing the configuration of an electronic device according to an embodiment.

Referring to FIG. 1, an electronic device 100 according to the embodiment may be a device that predicts and processes a lens defect using an artificial intelligence model, such as a tablet personal computer (PC), a mobile phone, a desktop PC, a laptop PC, or a netbook computer. However, the present invention is not limited thereto, and the electronic device 100 may be implemented as various types of devices capable of providing prediction information, such as a server or a PC.

A memory 110 may store data required for various embodiments of the present disclosure. The memory 110 may be implemented in the form of a memory embedded in the electronic device 100 or may be implemented in the form of a memory that can be attached/detached to/from the electronic device 100 depending on the purpose of data storage. For example, data for driving the electronic device 100 may be stored in a memory embedded in the electronic device 100, and data for expanding functions of the electronic device 100 may be stored in a memory that can be attached/detached to/from the electronic device 100. Meanwhile, the memory embedded in the electronic device 100 may be implemented as at least one of a volatile memory (for example, a dynamic RAM (DRAM), static RAM (SRAM), or synchronous dynamic RAM (SDRAM)) and a non-volatile memory (for example, a one-time programmable ROM (OTPROM), programmable ROM (PROM), erasable and programmable ROM (EPROM), electrically erasable and programmable ROM (EEPROM), mask ROM, flash ROM, flash memory (for example, NAND flash or NOR flash), hard drive, or solid state drive (SSD)). In addition, the memory that can be attached/detached to/from the electronic device 100 may be implemented in the form of a memory card (for example, compact flash (CF), secure digital (SD), Micro-secure digital (SD), Mini-SD, extreme digital (xD), multi-media card (MMC), and the like), an external memory that can be connected to a USB port (for example, USB memory), or the like.

As an example, the memory 110 may store a computer program including at least one instruction or instructions for controlling the electronic device 100.

As an example, the memory 110 may store information about a neural network (or neural network) model (or learning model, artificial intelligence model, and the like). Here, storing the information about the neural network model may mean storing various types of information related to the operation of the neural network model, for example, information about at least one layer included in the neural network model, information about parameters, biases, and the like used in each of the at least one layer, or the like. However, it goes without saying that the information about the neural network model may be stored in an internal memory of a processor 120 depending on the implementation form of the processor 120 described below. For example, when the processor 120 is implemented as dedicated hardware, the information about the neural network model may be stored in the internal memory of the processor 120.

Further, one or more processors 120 (hereinafter, processors) may be electrically connected to the memory 110 and may control the overall operation of the electronic device 100. The processor 120 may be composed of one or more processors. Specifically, the processor 120 may perform operations of the electronic device 100 according to various embodiments of the present disclosure by executing at least one instruction stored in the memory 110.

Further, according to the embodiment, the processor 120 may be implemented as a digital signal processor (DSP), a microprocessor, a graphics processing unit (GPU), an artificial intelligence (AI) processor, a neural processing unit (NPU), or a time controller (TCON) that processes a digital image signal. However, the present invention is not limited thereto, and may include or may be defined by one or more of a central processing unit (CPU), a micro controller unit (MCU), a micro processing unit (MPU), a controller, an application processor (AP), a communication processor (CP), or an ARM processor. Additionally, the processor 120 may be implemented as a system on chip (SoC) or large scale integration (LSI) with a built-in processing algorithm, or may be implemented in the form of an application specific integrated circuit (ASIC) or a field programmable gate array (FPGA).

According to the embodiment, the processor 120 may be implemented as a digital signal processor (DSP), a microprocessor, or a timing controller (TCON). However, the present invention is not limited thereto, and may include or may be defined by one or more of a central processing unit (CPU), a micro controller unit (MCU), a micro processing unit (MPU), a controller, an application processor (AP), a communication processor (CP), or an ARM processor. Additionally, the processor 120 may be implemented as a system on chip (SoC) or large scale integration (LSI) with a built-in processing algorithm, or may be implemented in the form of a field programmable gate array (FPGA).

In addition, the processor 120 for executing the neural network model in the electronic device and method according to the embodiment may be implemented through a combination of a general-purpose processor such as a CPU, an AP, or a digital signal processor (DSP), a graphics-only processor such as a GPU or a vision processing unit (VPU), or an artificial intelligence-only processor such as an NPU, and software.

Further, the processor 120 may be controlled to process input data according to predefined operation rules or neural network models stored in the memory 110. Alternatively, when the processor 120 is a dedicated processor (or a neural network dedicated processor), the processor 120 may be designed with a hardware structure specialized for processing a specific neural network model. For example, hardware specialized for processing a specific neural network model can be designed as a hardware chip such as an ASIC or FPGA. When the processor 120 is implemented as a dedicated processor, the processor 120 may be implemented to include a memory for implementing the embodiment of the present disclosure, or the processor 120 may be implemented to include a memory processing function for utilizing an external memory.

According to the embodiment, the processor 120 may input learning data into each neural network model and output results for defects.

Further, training of the neural network model may be performed through the electronic device 100, but is not limited thereto, and may also be performed through a separate server and/or system. Examples of learning algorithms include, but are not limited to, supervised learning, unsupervised learning, semi-supervised learning, or reinforcement learning.

Accordingly, the electronic device 100 may cluster a plurality of pieces of training data into a plurality of training data groups suitable for training a neural network model, and input the clustered data into a neural network model to train each neural network model. Accordingly, the performance of neural network models can be rapidly improved.

For example, the electronic device 100 may train through-focus data extracted through simulation or the like as training data by applying arbitrary changes to each element or feature that causes a lens defect.

Further, after performing learning, the electronic device 100 may output information on a lens defect or deformation from test through-focus data, which is test data, when the test through-focus data is input. That is, the electronic device 100 may output a lens defect result composed of the presence or absence of a lens defect, a type of defect (deformation information), and a degree of deformation.

Hereinafter, the method for predicting lens defects may be performed in the electronic device 100 described above. For example, each step or operation may be performed in the processor or memory of the electronic device 100. Hereinafter, each step or operation is described as operating in the processor of the electronic device 100.

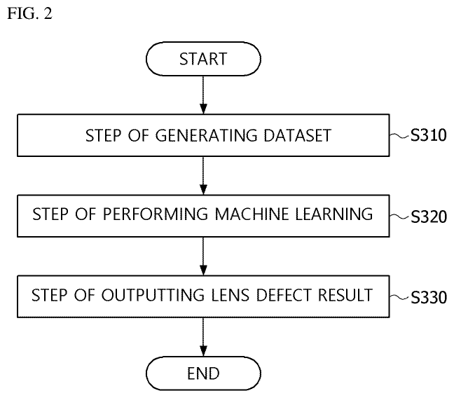

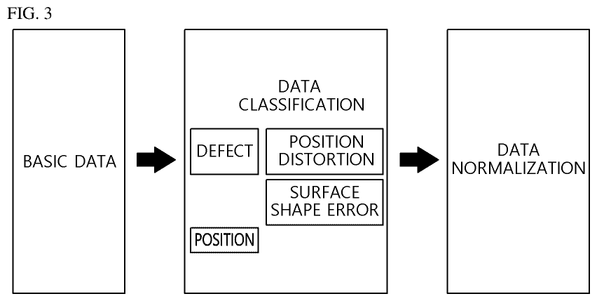

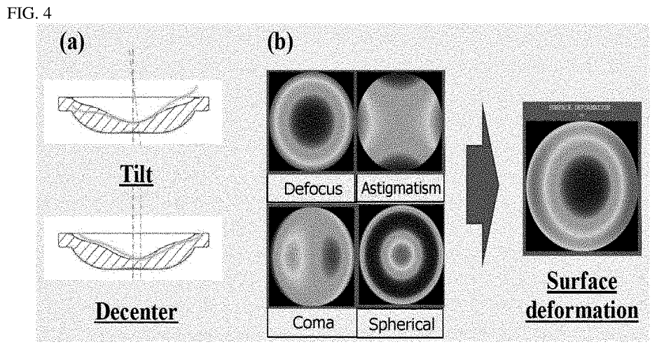

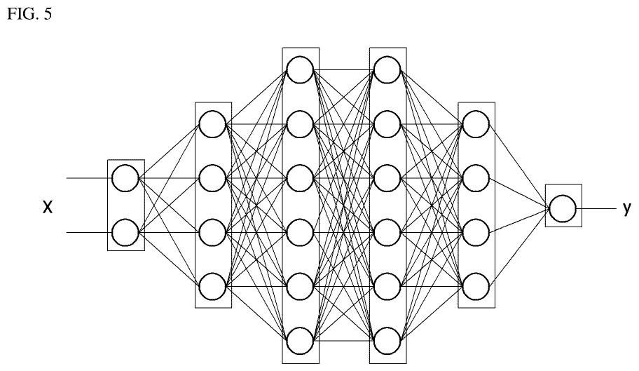

FIG. 2 is a flowchart for describing the method for predicting lens defects according to the embodiment, FIG. 3 is a view for describing a process of generating a dataset in the method for predicting lens defects according to the embodiment, FIG. 4 is a view for describing the lens defect in FIG. 3, and FIG. 5 is a view for describing a fully connected neural network in the method according to the embodiment.

Referring to FIG. 2, the method for predicting lens defects according to the embodiment may include a step (S310) of generating a dataset that is through-focus data by applying a predetermined lens defect, a step (S320) of performing machine learning based on the dataset, and a step (S330) of outputting a lens defect result when test through-focus data is input.

First, basic data may be subjected to a process, such as normalization, to generate a dataset. Specifically, the dataset that is through-focus data may be generated by applying a predetermined lens defect (S310).

Referring further to FIG. 3, once the basic data is obtained or input, data classification of the basic data may be performed, and then data normalization may be performed. In other words, the step of generating a dataset may include a step of classifying the dataset by the lens defect and a step of further classifying the classified dataset by position.

First, the basic data may include through-focus data to which a predetermined lens defect is applied. The basic data may be data obtained through through-focus and may be spatial frequency response data in a tangential T or sagittal S direction. For example, the basic data may be values (for example, peaks) of spatial frequency response data. In this case, a target lens may move in an optical axis direction for through-focus. The target lens may be one lens in a lens assembly or barrel. The through-focus data may be obtained in a state in which an additional lens other than the target lens is further disposed. For example, the through-focus data may be generated when one lens moves while a plurality of lenses are fixed, or when a lens assembly including at least one lens moves while another lens or assembly is fixed.

Data classification may be performed on the basic data. The data classification may be performed by lens defect type and position.

Referring further to FIG. 4, in the method according to the embodiment, the lens defect may include position distortion like FIG. 4A or a surface shape error like FIG. 4B. The position distortion may include tilt, decentering, and the like of the lens. The surface shape error may include defocus, astigmatism, coma, spherical aberration, and the like.

Surface deformation due to the position distortion, the surface shape error, or the like in FIGS. 4A and 4B may affect the spatial frequency response (SFR). That is, the position distortion or surface shape error may be a lens defect that affects the spatial frequency response.

The basic data may be classified by lens defect. Further, the basic data classified by lens defect may be further classified by position. The position may correspond to each region of interest where through-focus is performed. Here, the regions of interest may be located at the upper left (Left Top, LT), upper right (Right Top, RT), lower left (Left Bottom, LB), and lower right (Right Bottom, RB) based on a center of a target. That is, the spatial frequency response (SFR) for the regions of interest (ROI) of the target may be classified by the region of interest. A detailed explanation of this will be provided below.

Further, machine learning may be performed (S320). The machine learning may be performed based on a multi-output regression model or method (multi-output regression method). The multi-output regression method may utilize techniques such as a random forest technique, a stochastic gradient boosting technique, and the like that can perform regression analysis or classification analysis, but is not limited thereto. In addition, the least absolute shrinkage and selection operator (LASSO) technique, which can examine variable importance by discarding the coefficients of unimportant variables by penalizing the regression equation, may also be utilized. In this step, training and testing are performed for each lens defect (position) to verify performance, and then the optimal machine learning model may be utilized depending on the size and characteristics of the dataset.

Further, the electronic device may output a lens defect result (S330). The lens defect result may be predicted based on a multi-output regression model, which is a machine learning model.

Specifically, the machine learning may be based on a fully connected neural network that follows a Gaussian distribution (N-Gaussian) for defects in a single lens.

Referring further to FIG. 5, the machine learning may be performed with a neural network having a plurality of hidden layers. For example, a lens defect (or result) may be predicted based on one input feature. In this way, even when the generation of the dataset and the performance of machine learning are performed in opposite directions in the method and electronic device according to the embodiment, the interference of supervised learning due to these opposite directions can be resolved. That is, although the generation of the dataset is performed with through-focus data obtained by applying changes in defects, the supervised learning may be performed to predict defects based on the through-focus data. Further, the ambiguity of the inverse neural network may be removed as the specific values are estimated using the probability density function (pdf) of a fully connected neural network that follows a Gaussian distribution (N-Gaussian) for the specific values.

Additionally, the machine learning may be applied to predict a defect in a single lens by weighting Gaussian distributions. Therefore, the prediction method according to the embodiment can easily eliminate uncertainty in the prediction.

Furthermore, in the machine learning according to the embodiment, the distribution of lens defects may follow a Gaussian distribution based on a threshold value that determines pass/fail. In this way, data imbalances can also be easily resolved.

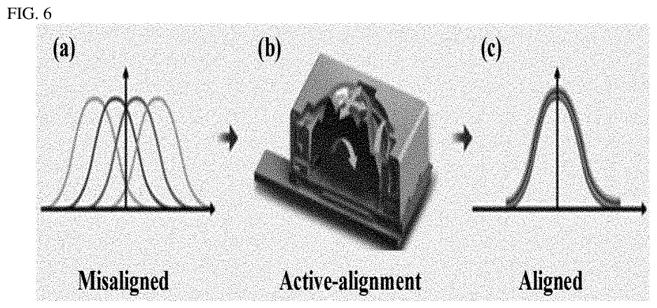

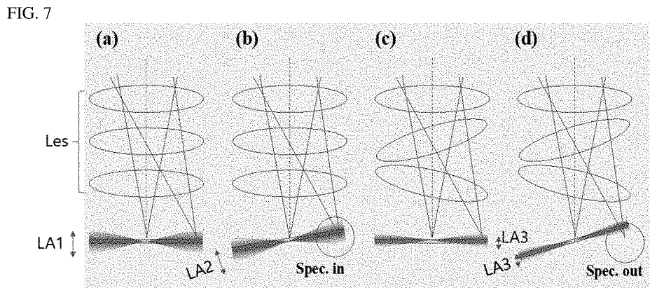

FIG. 6 is a view for describing active alignment to describe the effect of the method according to the embodiment, and FIG. 7 is a view for describing the effect of the method according to the embodiment.

Referring to FIGS. 6 and 7, according to the embodiment, active alignment (AA) may refer to a manufacturing process used for aligning an image sensor of a camera module to the lens assembly. The goal of the active alignment (AA) is to ensure that the image sensor is accurately positioned relative to the lens assembly to achieve optimal image quality. Further, the accuracy and consistency of the assembly process can be improved by using the active alignment (AA) in camera module manufacturing, thereby increasing production yield. Additionally, the active alignment (AA) can improve the overall image quality of the camera module by reducing image distortion, improving sharpness, and enhancing contrast.

This active alignment (AA) process may involve the use of a feedback loop that adjusts the position of the image sensor in real time based on feedback from a camera optical device. Specifically, the feedback loop may be achieved by using an algorithm to analyze the images captured by the camera module and calculate the precise adjustments required to align the sensor to the lens assembly.

Furthermore, as shown in FIG. 6A, it means that the through-focus (or focus passing) (TF) data of a plurality of corners (for example, four corners) obtained by moving in the optical axis direction or a Z-axis direction are misaligned with each other. This may be a result of a first feedback loop.

Afterward, a second feedback loop may calculate a tilt compensation angle so that a gripper holding the lens assembly or barrel is compensated for an angle in an x or y direction that is a direction perpendicular to an optical axis, as shown in FIG. 6B.

As a result, the through-focus (TF) data of the four corners may be aligned as shown in FIG. 6C. The active alignment process is then completed by applying epoxy and allowing the epoxy to cure.

In this case, FIGS. 6A and 6C each represent data through misaligned and aligned foci at different positions in the same field. However, during the active alignment process, a defect may occur in some samples. For example, when correcting the angle in the x or y direction, there may be an error due to mechanical tolerance, and deformation of the curing material (for example, epoxy) may occur during the curing process, which may cause the tilt to occur again.

That is, in the active alignment (AA) process, pass or fail is determined based on the spatial frequency response (SFR) expressed as the image quality of the module, and as described above, various issues (for example, tolerance) occurring in the active alignment (AA) process may cause a certain slope, which lowers the SFR value.

Furthermore, since lens assembly manufacturing also has its own errors, when these issues arise in lens production tolerances, performance may be reduced. The method and electronic device according to the embodiment may predict a defect or failure in the manufacturing of these lens assemblies.

Additionally, during the manufacturing process of these lens assemblies, the tilt margin between a precisely manufactured lens assembly and a somewhat imprecisely manufactured lens assembly may change, which may also affect the margin of active alignment.

FIG. 7A shows a lens without barrel tilt, FIG. 7B shows a lens with barrel tilt, FIG. 7C shows a defective lens without barrel tilt, and FIG. 7D shows a defective lens with barrel tilt. In FIG. 7, the blue region represents the tilt margin of each lens.

In this case, precisely manufactured lenses, such as those shown in FIGS. 7A and 7B, may have larger tilt margins LA1 and LA2 in the blue region, resulting in increased tilt tolerance. In contrast, tilt margins LA3 and LA4 may be small for lenses that are manufactured somewhat inaccurately, as in FIGS. 7C and 7D.

In this way, a lens defect may be predicted in both the lens assembly and the active alignment (AA) process by the method and electronic device according to the embodiment. This makes it easier to determine component defects in optical components (for example, lenses) in the lens assembly and to accurately analyze the cause of abnormal phenomena, thereby making it easier to identify the causes of issues occurring in lens assembly and production. This can ultimately improve production efficiency and product quality.

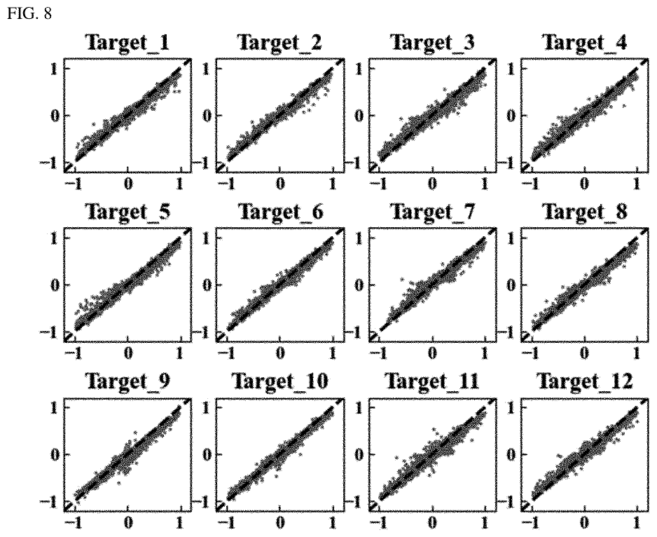

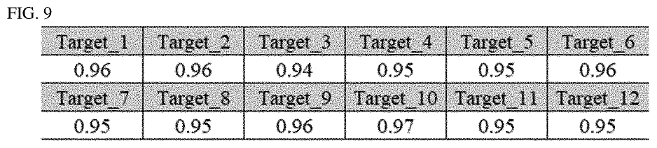

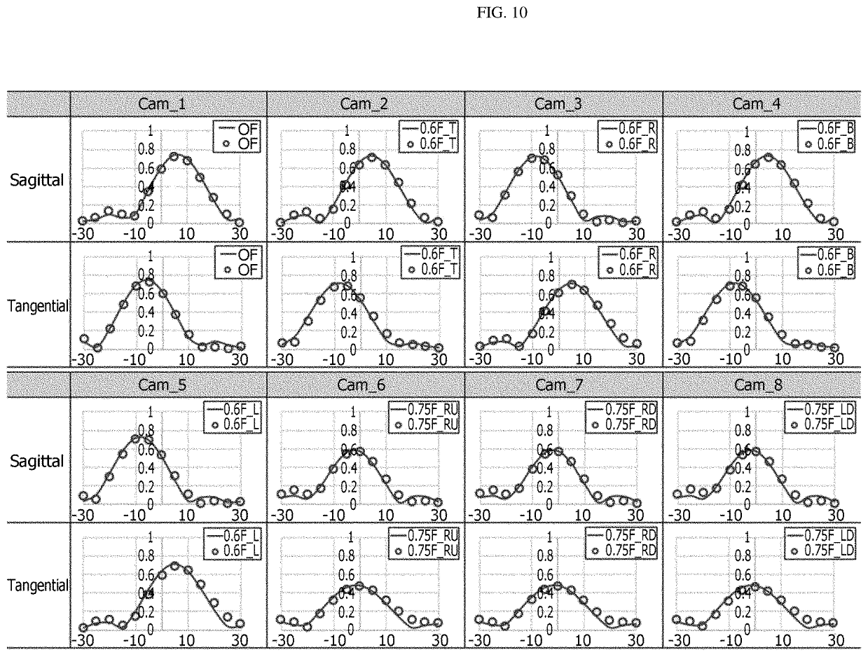

FIG. 8 is a scatter plot of predicted values and actual values by the method according to the embodiment, FIG. 9 is an evaluation index (R-Squared) for the method according to the embodiment, and FIG. 10 is a view showing through-focus data of predicted values and actual values by the method according to the embodiment.

### Experiments and Experimental Results

As experimental conditions, the trained model was evaluated using a test set of 9,554 items. Among a total of 112 target variables, the evaluation focused on 12 key variables. Further, as an evaluation index for the multi-output regression model, the R-squared value was used, which indicates how well the model explains the changes between actual and predicted values. Mean squared error (MSE), mean absolute error (MAE), and root mean squared error (RMSE) may be used as evaluation indicators for the multi-output regression model.

Referring to FIG. 8, FIG. 8 shows a scatter plot of the relationship between actual values and predicted values for the 12 targets described above. Here, an x-axis and y-axis each represent the actual and predicted values and each of the values is normalized within the range of −1 to 1 using the same scale.

Further, the R-squared values for each target can be confirmed in FIG. 9, and all of them exceed 0.94, indicating that the model of machine learning according to the method and electronic device according to the embodiment has excellent performance in predicting major variables.

Furthermore, the accuracy of the model was further verified through cross-validation. For cross-validation, a method where the predicted target values of the raw through-focus (TF) data were applied back to a geometric optics simulation to compute the through-focus (TF), which was then compared with the original raw data was used.

FIG. 10 shows through-focus (TF) data in the sagittal and tangential directions for each of eight fields.

In FIG. 10, the solid line indicates actual data and the dots indicate through-focus (TF) data calculated using the predicted target values. The similarity between graphs was also calculated using the R-squared value, which was 0.96, confirming the high predictive accuracy of the model.

In FIG. 10, ‘F’ refers to a field. Further, ‘T’ refers to top, ‘R’ refers to right, ‘B’ refers to bottom, and ‘L’ refers to left. Also, ‘LT (LU)’ refers to left top, ‘RT (RU)’ refers to right top, ‘LB (LD)’ refers to left bottom, and ‘RB (RD)’ refers to right bottom. It may be located. The spatial frequency response (SFR) may be obtained at each of the upper left (LT, Left Top), upper right (RT, Right Top), lower left (LB, Left Bottom), and lower right (RB, Right Bottom). Furthermore, tangential T may correspond to vertical V, and sagittal S may correspond to horizontal H.

The method and electronic device for predicting lens defects according to the disclosed embodiment may be implemented in the form of program commands that can be executed through various computer means and recorded on a computer-readable medium. Additionally, the embodiment of the present disclosure may be a computer-readable recording medium having recorded thereon one or more programs including commands for executing the method and electronic device for predicting lens defects.

Further, the above computer-readable medium may include program commands, data files, data structures, and the like independently or in combination. The program commands recorded on the above medium may be specially designed and configured for the present invention or may be known and available to those skilled in the art of computer software. Examples of computer-readable recording media may include magnetic media such as hard disks, floppy disks, and magnetic tapes, optical media such as CD-ROMs and DVDs, magneto-optical media such as floptical disks, and hardware devices specifically configured to store and execute program instructions such as ROMs, RAMs, and flash memories. Examples of program instructions may include machine language code, such as that produced by a compiler, as well as high-level language code that can be executed by a computer using an interpreter or the like.

Here, the device-readable storage medium may be provided in the form of a non-transitory storage medium. Here, ‘non-transitory’ simply means that the storage medium is a tangible device and does not contain signals (for example, electromagnetic waves), and the term does not distinguish between cases where data is stored semi-permanently or temporarily on the storage medium. For example, a ‘non-transitory storage medium’ may include a buffer in which data is temporarily stored.

According to one embodiment, a method and electronic device for predicting lens defects according to various embodiments disclosed in the present document may be provided by being included in a computer program product. Computer program products may be traded between sellers and buyers as commodities. The computer program product may be distributed in the form of a machine-readable storage medium (for example, compact disc read-only memory (CD-ROM)), or may be distributed online (for example, by download or upload) through an application store (for example, Play Store™) or directly between two user devices (for example, smartphones). In the case of online distribution, at least a portion of the computer program product (for example, a downloadable app) may be temporarily stored or temporarily generated in a device-readable storage medium, such as the memory of a server of a manufacturer, a server of an application store, or an intermediary server.

Specifically, the method for predicting lens defects according to the disclosed embodiment and the computer program product including a recording medium storing a program for causing an electronic device to perform the method may be implemented.

Although the embodiment has been described in detail above, the scope of the present invention is not limited thereto, and various modifications and improvements made by those skilled in the art using the basic concept of the present invention defined in the following claims also fall within the scope of the present invention.

The term ‘~portion’ used in this embodiment means a software or hardware component such as a field-programmable gate array (FPGA) or ASIC, and the ‘~portion’ performs any roles. However, the term ‘~portion’ is not limited to software or hardware. The term ‘~portion’ may be configured to reside on an addressable storage medium and may be configured to cause one or more processors to operate the processors. Thus, as an example, the term ‘~portion’ includes components such as software components, object-oriented software components, class components, and task components, as well as processes, functions, attributes, procedures, subroutines, segments of program code, drivers, firmware, microcode, circuits, data, databases, data structures, tables, arrays, and variables. The functionality provided in the components and ‘~sub-components’ may be combined into a smaller number of components and ‘~sub-components’ or further separated into additional components and ‘~sub-components.’ Additionally, components and ‘~portions’ may be implemented to regenerate one or more CPUs in a device or secure a multimedia card.

Although the above description focuses on examples, these are merely examples and do not limit the present invention. Those skilled in the art will appreciate that various modifications and applications not exemplified above are possible without departing from the essential characteristics of the present invention. For example, each component specifically shown in the examples may be modified and implemented. Further, the differences related to these modifications and applications should be construed as being included within the scope of the present invention as defined in the appended claims.

1. An electronic device for predicting lens defects, comprising:
a memory; and
a processor connected to the memory,
wherein the processor generates a dataset that is through-focus data by applying a predetermined lens defect, performs machine learning based on the dataset, and outputs a lens defect result when test through-focus data is input.

2. The electronic device of claim 1, wherein the predetermined lens defect includes position distortion or a surface shape error.

3. The electronic device of claim 1, wherein the processor classifies the dataset by the lens defect when generating the dataset.

4. The electronic device of claim 3, wherein the processor further classifies the classified dataset by position.

5. The electronic device of claim 1, wherein the machine learning is based on a fully connected neural network that follows a Gaussian distribution (N-Gaussian) for defects in a single lens.

6. The electronic device of claim 1, wherein, in the machine learning, a distribution of lens defects is set to follow a Gaussian distribution based on a threshold value that determines pass/fail.

7. The electronic device of claim 6, wherein the machine learning predicts a defect of a single lens by weighting the Gaussian distribution.

8. The electronic device of claim 1, wherein the generation of the dataset and the performance of the machine learning are performed in opposite directions.

9. The electronic device of claim 1, wherein the through-focus data is a spatial frequency response in a tangential T or sagittal S direction.

10. The electronic device of claim 1, wherein the lens defect result is predicted based on a multi-output regression model.

11. A method for predicting lens defects, comprising:
generating a dataset that is through-focus data by applying a predetermined lens defect;
performing machine learning based on the dataset; and
outputting a lens defect result when test through-focus data is input.

12. The method of claim 11,
wherein the predetermined lens defect includes position distortion or a surface shape error.

13. The method of claim 11,
wherein the step of generating the dataset includes a step of classifying the dataset by the lens defect.

14. The method of claim 13,
wherein the method further includes a step of further classifying the classified dataset by position.

15. The method of claim 11,
wherein the machine learning is based on a fully connected neural network that follows a Gaussian distribution (N-Gaussian) for defects in a single lens.

16. The method of claim 11,
wherein in the machine learning, a distribution of lens defects is set to follow a Gaussian distribution based on a threshold value that determines pass/fail.

17. The method of claim 16,
wherein the machine learning predicts a defect of a single lens by weighting the Gaussian distribution.

18. The method of claim 11,
wherein the generation of the dataset and the performance of the machine learning are performed in opposite directions.

19. The method of claim 11,
wherein the through-focus data is a spatial frequency response in a tangential (T) direction or a sagittal (S) direction.

20. The method of claim 11,
wherein in the outputting step, the lens defect result is predicted based on a multi-output regression model.
